(19) United States
(12) Patent Application Publication
(10) Pub. No.: US 2024/0404454 A1
(43) Pub. Date: Dec. 5, 2024

(54) DISPLAY DEVICE

(71) Applicant: Samsung Display Co., Ltd., Yongin-si (KR)

(72) Inventor: Eunhee HAN, Yongin-si (KR)

(73) Assignee: Samsung Display Co., Ltd., Yongin-si (KR)

(21) Appl. No.: 18/623,467

(22) Filed: Apr. 1, 2024

(30) Foreign Application Priority Data
May 31, 2023 (KR) 10-2023-0069970

(51) Int. Cl. G09G 3/32

(52) U.S. Cl. CPC G09G 3/32; G09G 2310/0275; G09G 2380/02

(57) ABSTRACT

A display device that includes multiple inorganic layers having an opening defined in at least some of the inorganic layers, a pixel driving circuit disposed in a region defined by the opening in a plan view, and a light emitting element electrically connected to the pixel driving circuit. The at least some of the inorganic layers include an inorganic stacked structure disposed in the region defined by the opening. The inorganic stacked structure has a substantially polygonal or circular shape including a corner region having an outwardly convex curve in a plan view.

### CROSS-REFERENCE TO RELATED APPLICATIONS

This application claims priority under 35 U.S.C. § 119 from Korean Patent Application No. 10-2023-0069970 filed on May 31, 2023 in the Korean Intellectual Property Office, the entire contents of which are incorporated herein by reference.

### BACKGROUND

### 1. Technical Field

The disclosure herein relates to a flexible display device.

### 2. Description of the Related Art

Electronic devices such as smart phones, tablet computers, laptop computers, automotive navigation system units, and smart televisions are being developed. Such electronic devices may be provided with a display device in order to provide information.

In order to satisfy the UX/UI of a user, display devices in various shapes are being developed. Among the display devices, flexible display devices are being actively developed.

### SUMMARY

The disclosure provides a display panel with improved impact resistance.

An embodiment provides a display device that may include a base layer including a plurality of element regions and a boundary region adjacent to the plurality of element regions, a plurality of inorganic layers disposed on the base layer and including an opening defined in at least some of the inorganic layers, the opening corresponding to the boundary region, an organic layer disposed inside the opening and disposed on the plurality of inorganic layers, a pixel driving circuit disposed between the base layer and the organic layer and disposed in each of the plurality of element regions, and a light emitting element disposed on the organic layer and electrically connected to the pixel driving circuit. In an embodiment, the at least some of the inorganic layers may include an inorganic stacked structure defined by the opening and disposed in each of the plurality of element regions, the opening may surround the inorganic stacked structure in a plan view, the inorganic stacked structure may have a substantially polygonal shape in a plan view and include a corner region, the corner region having a shape selected from an outwardly convex curve shape and a circular shape in a plan view.

The inorganic stacked structure may have a substantially square shape in a plan view.

Each of the plurality of element regions may include a first pixel region and a second pixel region, the pixel driving circuit may include a first pixel driving circuit and a second pixel driving circuit respectively disposed in the first pixel region and the second pixel region, the light emitting clement may include a first light emitting clement and a second light emitting element respectively electrically connected to the first pixel driving circuit and the second pixel driving circuit.

The plurality of element regions may include a first-type clement region and a second-type element region, the first light emitting element corresponding to the first-type element region and the first light emitting element corresponding to the second-type element region may generate light of different colors, and the second light emitting element corresponding to the first-type element region and the second light emitting element corresponding to the second-type element region may generate light of a same color.

The plurality of element regions may define a plurality of rows, and the first-type element region and the second-type element region may be alternately disposed in each of the plurality of rows.

The light emitting element may overlap the opening in a plan view.

The pixel driving circuit may include a transistor electrically connected to the light emitting element, the transistor may not overlap the opening.

The display device may further include a data line electrically connected to the transistor, the data line may overlap the opening.

The data line may be disposed on the organic layer.

The transistor may include a silicon transistor that may include a silicon semiconductor pattern and an oxide transistor may include an oxide transistor pattern, the silicon semiconductor pattern and the oxide semiconductor pattern may be disposed on different ones of the plurality of inorganic layers.

The display device may also include a thin film encapsulation layer covering the light emitting element, an input sensor disposed on thin film encapsulation layer, and a color filter disposed on the input sensor and overlapping the light emitting element in a plan view.

The display device may be capable of being folded or rolled on a roller.

The plurality of clement regions may be completely surrounded by the boundary region in a plan view.

In an embodiment, a display device includes a base layer including a plurality of element regions and a boundary region adjacent to the plurality of element regions, a plurality of inorganic layers disposed on the base layer and including an opening defined in at least some of the inorganic layers, the opening may correspond to the boundary region, the opening may surround at least a first element region among the plurality of element regions in a plan view, an organic layer disposed inside the opening, disposed on the plurality of inorganic layers, and overlapping the first element region, a transistor disposed between the base layer and the organic layer and disposed in the first element region, and a light emitting element disposed on the organic layer and electrically connected to the transistor. In an embodiment, an inner surface of the at least some of the inorganic layers defining the opening surrounding the first element region may have a substantially polygonal shape including corners having a shape selected from an outwardly convex curve shape and a circular shape in a plan view.

In an embodiment, a display device includes a base layer including a plurality of element regions and a boundary region adjacent to the plurality of clement regions, a plurality of inorganic layers disposed on the base layer and including an opening defined in at least some of the inorganic layers, the opening corresponding to the boundary region, an organic layer disposed inside the opening and disposed on the plurality of inorganic layers in a plan view, a pixel driving circuit disposed between the base layer and the organic layer, the pixel driving circuit disposed in each of the plurality of clement regions, and a light emitting clement disposed on the organic layer and electrically connected to the pixel driving circuit. In an embodiment, the at least some of the inorganic layers may define an inorganic stacked structure for each of the plurality of element regions, the inorganic stacked structure may have a circular shape in a plan view, and the plurality of element regions and the boundary region may be divided into a plurality of unit regions, each of which has a hexagonal shape in a plan view, the plurality of element regions and the plurality of unit regions have a one-to-one correspondence, a center of the hexagonal shape and a center of the circular shape may be coincident.

The inorganic stacked structure may occupy an area in a range of about 80% to about 90% of an area of each of the plurality of unit regions.

Each of the plurality of element regions may include a first pixel region and a second pixel region, the pixel driving circuit may include a first pixel driving circuit and a second pixel driving circuit respectively disposed in the first pixel region and the second pixel region, the light emitting element may include a first light emitting element and a second light emitting element respectively electrically connected to the first pixel driving circuit and the second pixel driving circuit.

The plurality of element regions may include a first-type element region and a second-type element region, the first light emitting element corresponding to the first-type element region and the first light emitting element corresponding to the second-type element region may generate light of different colors, and the second light emitting element corresponding to the first-type element region and the second light emitting element corresponding to the second-type element region may generate light of a same color.

The light emitting element may overlap the opening in a plan view, the pixel driving circuit may include a transistor electrically connected to the light emitting element, and the transistor and the opening may not overlap in a plan view.

The display device may also include a thin film encapsulation layer covering the light emitting element, an input sensor disposed on the thin film encapsulation layer, and a color filter disposed on the input sensor and overlapping the light emitting element.

### BRIEF DESCRIPTION OF THE DRAWINGS

These and/or other aspects will become apparent and more readily appreciated from the following description of the embodiments, taken in conjunction with the accompanying drawings in which:

FIG. 1A to FIG. 1C are perspective views of an electronic device according to an embodiment;

FIG. 2 is an exploded perspective view of an electronic device according to an embodiment;

FIG. 3 is a plan view of a display panel according to an embodiment;

FIG. 4A is a schematic diagram of an equivalent circuit of a pixel according to an embodiment;

FIG. 4B is a plan view of a display region of a display panel according to an embodiment;

FIG. 4C is a schematic cross-sectional view of a display module according to an embodiment;

FIG. 5A and FIG. 5B are plan views of a display region of a display panel according to an embodiment;

FIG. 6A and FIG. 6B are plan views of a display region of a display panel according to an embodiment;

FIG. 7A is a plan view of a display region of a display panel according to an embodiment; and

FIG. 7B is a plan view of one enlarged unit region.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that may not be perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, may not be necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scopes. Further, the blocks, parts, and/or modules of some embodiments may be physically combined into more complex blocks, parts, and/or modules without departing from the scopes.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

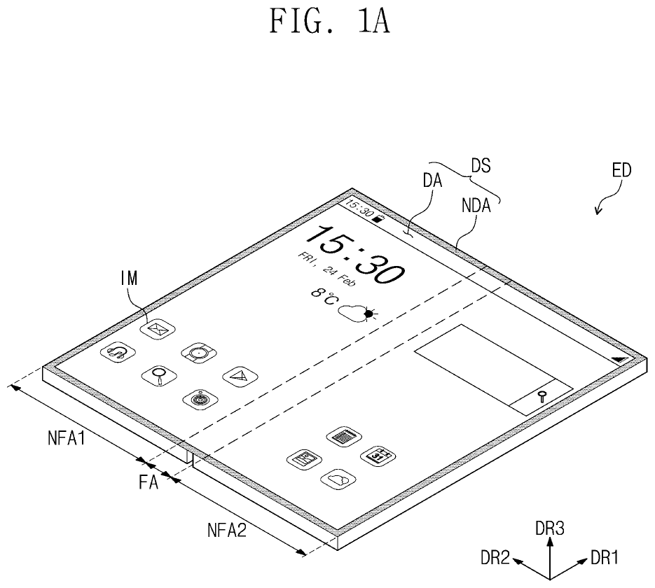

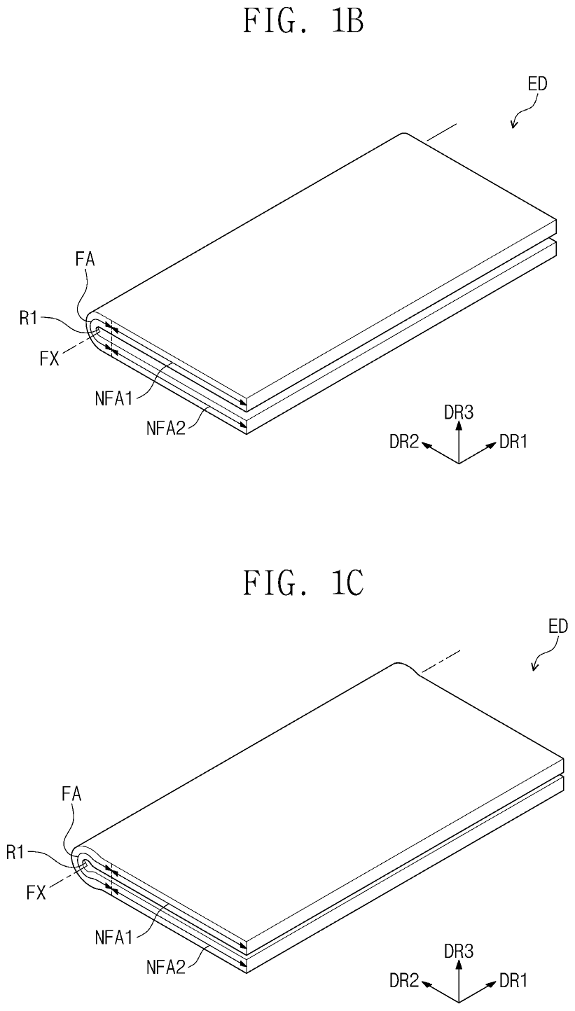

FIG. 1A to FIG. 1C are perspective views of an electronic device ED according to an embodiment. FIG. 1A illustrates the electronic device ED in an unfolded state, and FIG. 1B and FIG. 1C illustrate the electronic device ED in a folded state.

Referring to FIG. 1A to FIG. 1C, the electronic device ED according to an embodiment may include a display surface DS defined by a first direction DR1 and a second direction DR2 intersecting the first direction DR1. The electronic device ED may provide an image IM to a user through the display surface DS.

The display surface DS may include a display region DA and a non-display region NDA around the display region DA. The display region DA may display the image IM, and the non-display region NDA might not display the image IM. The non-display region NDA may surround the display region DA. However, the embodiment may not be limited thereto, and the shape of the display region DA and the shape of the non-display region NDA may vary.

Hereinafter, a direction substantially perpendicular to and intersecting a plane defined by the first direction DR1 and the second direction DR2 may be defined as a third direction DR3. The third direction DR3 may be a reference for distinguishing the front surface (or, upper surface) and the rear surface (or, lower surface) of each member. In the disclosure, “in a plan view” may be defined as a state viewed in the third direction DR3. Hereinafter, the first to third directions DR1, DR2, and DR3 may be directions respectively indicated by first to third directional axes and may be given the same reference numerals.

The electronic device ED may include a folding region FA and multiple non-folding regions NFA1 and NFA2. The non-folding regions NFA1 and NFA2 may include a first non-folding region NFA1 and a second non-folding region NFA2. In the second direction DR2, the folding region FA may be disposed between the first non-folding region NFA1 and the second non-folding region NFA2.

The electronic device ED of a first mode may be defined as being in an unfolded state, and the electronic device ED of a second mode may be defined as being in a folded state. As the electronic device ED changes from the first mode to the second mode, the shape of the folding region FA changes, but the shapes of the non-folding regions NFA1 and NFA2 do not change.

As illustrated in FIG. 1B, the folding region FA may be folded with respect to a folding axis FX parallel to the first direction DR1. The folding region FA has a curvature (e.g., a predetermined or selectable curvature) and a radius of curvature (e.g., a predetermined or selectable radius of curvature) R1. The first non-folding region NFA1 and the second non-folding region NFA2 may face each other, and the electronic device ED may be inner-folded such that the display surface DS may not be exposed to the outside.

In an embodiment, the electronic device ED may be outer-folded such that the display surface DS may be exposed to the outside. In an embodiment, the electronic device ED may be configured such that an inner-folding or outer-folding operation may be alternatively repeated from an un-folding operation, but the embodiment may not be limited thereto. In an embodiment, the electronic device ED may be configured to select one of the un-folding operation, the inner-folding operation, and the outer-folding operation.

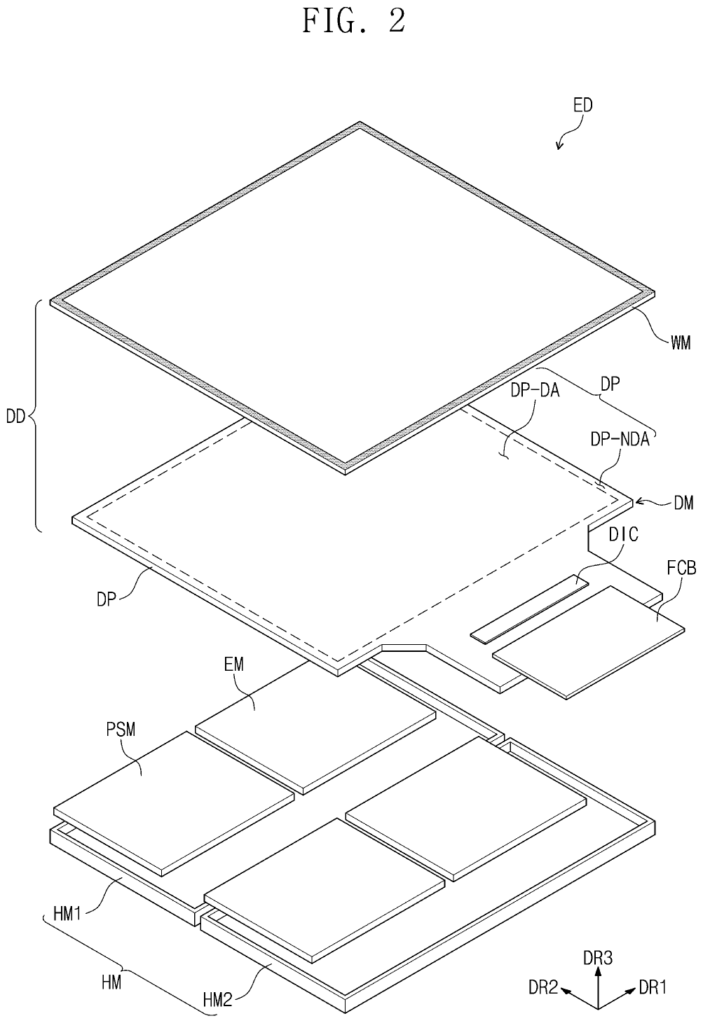

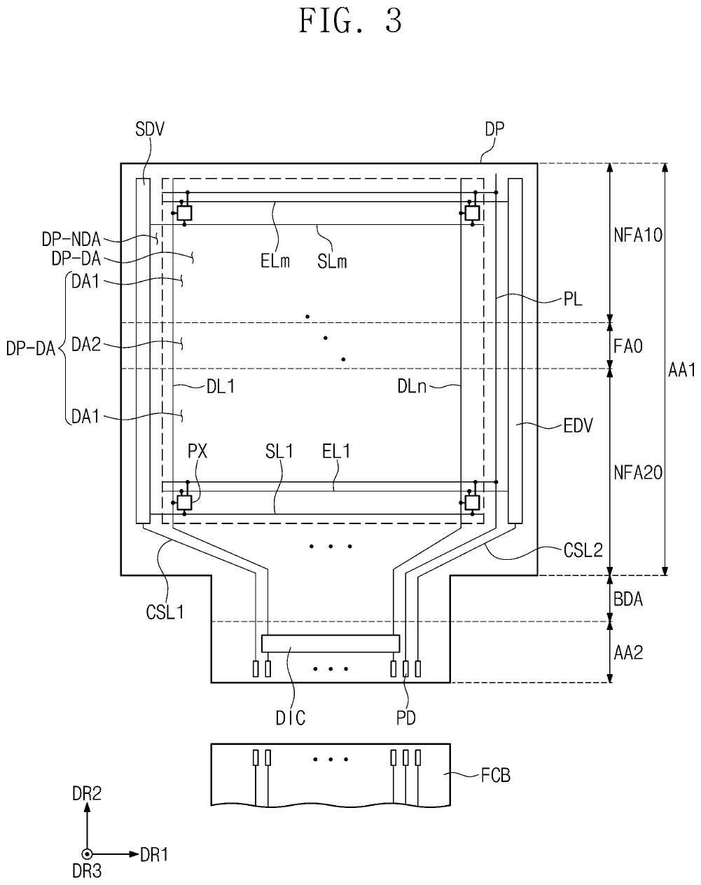

As illustrated in FIG. 1B, the distance between the first non-folding region NFA1 and the second non-folding region NFA2 may be substantially the same as two times the radius of curvature R1, but as illustrated in FIG. 1C, the distance between the first non-folding region NFA1 and the second non-folding region NFA2 may be less than two times the radius of curvature R1. FIG. 1B and FIG. 1C are illustrated with respect to the display surface DS, and a housing HM (see FIG. 2) forming the appearance of the electronic device ED may be in contact in end regions of the first non-folding region NFA1 and the second non-folding region NFA2.

FIG. 1A to FIG. 1C exemplarily illustrate a foldable electronic device, but a display device according to an embodiment may be applied to an electronic device other than the foldable electronic device. The display device according to an embodiment may also be applied to a rollable electronic device or a flat-panel electronic device. The display device according to an embodiment may be applied to medium and large-sized electronic devices other than a small electronic device such as a mobile phone.

FIG. 2 is an exploded perspective view of the electronic device ED according to an embodiment.

As illustrated in FIG. 2, the electronic device ED may include a display device DD, an electronic module EM, a power module PSM, and a housing HM. Although not separately illustrated, the electronic device ED may further include an instrument structure for controlling a folding operation of the display device DD.

The display device DD may generate an image and may sense an external input. The display device DD includes a window WM and a display module DM. The window WM may provide the front surface of the electronic device ED.

The display module DM may include at least a display panel DP. FIG. 2 illustrates only the display panel DP among stacked structures of the display module DM, but the display module DM may further include multiple components disposed on an upper side of the display panel DP. The stacking structure of the display module DM will be described in detail later. The type of display panel DP may not be particularly limited, and may be, for example, a light emitting-type display panel such as an organic light emitting display panel or an inorganic light emitting display panel.

The display panel DP includes a display region DP-DA and a non-display region DP-NDA respectively corresponding to the display region DA (see FIG. 1A) and the non-display region NDA (see FIG. 1A) of the electronic device ED. In the disclosure, the phrase “a region/portion corresponds to a region/portion,” means that the region/portion overlaps the region/portion, and the regions/portions may not be limited to having a same area.

As illustrated in FIG. 2, a driving chip DIC may be disposed in the non-display region DP-NDA of the display panel DP. A flexible circuit board FCB may extend to the non-display region DP-NDA of the display panel DP. The flexible circuit board FCB may be electrically connected to a main circuit board. The main circuit board may be an electronic component constituting the electronic module EM.

The driving chip DIC may include driving elements for driving a pixel of the display panel DP, for example, a data driving circuit. FIG. 2 illustrates a structure in which the driving chip DIC may be mounted on the display panel DP, but the inventive concept may not be limited thereto. For example, the driving chip DIC may be mounted on the flexible circuit board FCB.

The electronic module EM may include a control module, a wireless communication module, an image input module, a sound input module, a sound output module, a memory, an external interface module, and the like. The electronic module EM may include the main circuit board, and the above modules may be mounted on the main circuit board, or may be electrically connected to the main circuit board through a flexible circuit board. The electronic module EM may be electrically connected to the power module PSM.

Referring to FIG. 2, the electronic module EM may be disposed in each of a first housing HM1 and a second housing HM2, and the power module PSM may be disposed in each of the first housing HM1 and the second housing HM2. Although not illustrated, the electronic module EM disposed in the first housing HM1 and the electronic module EM disposed in the second housing HM2 may be electrically connected through a flexible circuit board.

Although not separately illustrated, the electronic device ED may further include an electronic optical module. The electronic optical module may be an electronic component configured to output or receive an optical signal. The electronic optical module may include a camera module and/or a proximity sensor. The camera module may capture an external image through a partial region of the display panel DP.

The housing HM illustrated in FIG. 2 may extend to the display device DD, particularly the window WM, to house the above other modules. The housing HM may be illustrated as including the first and second housings HM1 and HM2 separated from each other, but the embodiment may not be limited thereto. Although not illustrated, the electronic device ED may further include a hinge structure for connecting the first and second housings HM1 and HM2.

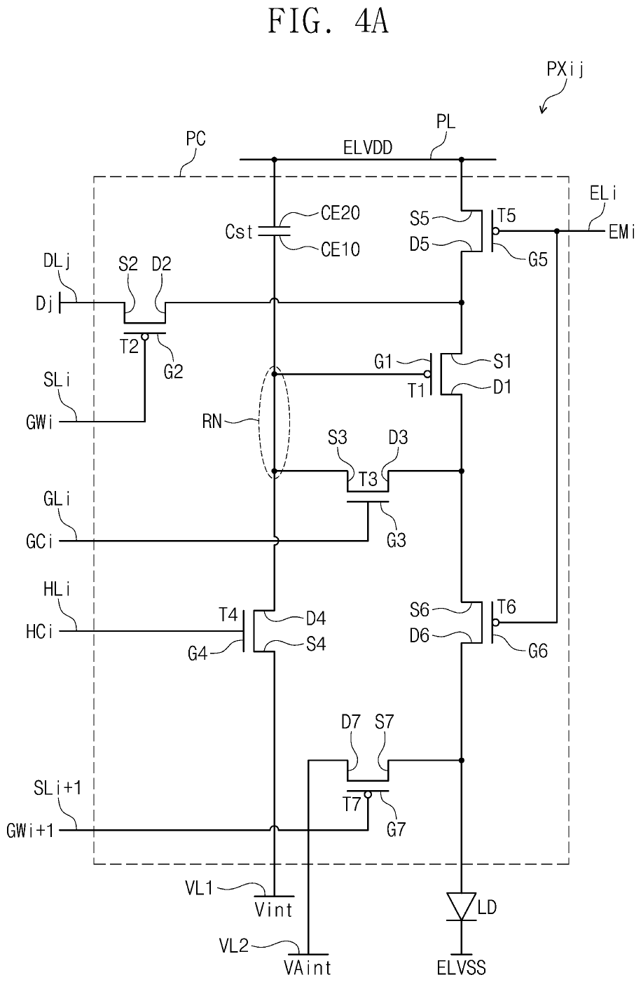

FIG. 3 is a plan view of the display panel DP according to an embodiment.

Referring to FIG. 3, the display panel DP may include the display region DP-DA and the non-display region DP-NDA around the display region DP-DA. A pixel PX may be disposed in the display region DP-DA. A scan driver SDV, a data driver, and an emission driver EDV may be disposed in the non-display region DP-NDA. The data driver may be a part of a circuit configured in the driving chip DIC illustrated in FIG. 3.

The display panel DP may include a first region AA1, a second region AA2, and a bending region BDA distinguished along the second direction DR2. The second region AA2 and the bending region BDA may be partial regions of the non-display region DP-NDA. The bending region BDA may be disposed between the first region AA1 and the second region AA2.

The first region AA1 may be a region corresponding to the display surface DS of FIG. 1A. The first region AA1 may include a first non-folding region NFA10, a second non-folding region NFA20, and a folding region FA0. The first non-folding region NFA10, the second non-folding region NFA20, and the folding region FA0 respectively correspond to the first non-folding region NFA1, the second non-folding region NFA2, and the folding region FA of FIG. 1A to FIG. 1C.

The display region DP-DA may include two first display regions DAI corresponding to the first non-folding region NFA10 and the second non-folding region NFA20 and a second display region DA2 corresponding to the folding region FA0. In the first direction DR1, the length of the bending region BDA and the length of the second region AA2 may be smaller than the length of the first region AA1. A region having a short length in a bending axis direction may be more readily bent.

The display panel DP may include multiple pixels PX, multiple scan lines SL1 to SLm, multiple data lines DL1 to DLn, multiple emission lines EL1 to ELm, first and second control lines CSL1 and CSL2, a first voltage line PL, and multiple pads PD. Here, m and n may be natural numbers. The pixels PX may be electrically connected to the scan lines SL1 to SLm, the data lines DLI to DLn, and the emission lines ELI to ELm. The display panel DP may include multiple scan lines, but FIG. 3 exemplarily illustrates a first group of scan lines SL1 to SLm.

The first group of scan lines SL1 to SLm may extend in the first direction DR1 and are electrically connected to the scan driver SDV. The data lines DL1 to DLn may extend in the second direction DR2, and may be electrically connected to the driving chip DIC via the bending region BDA. The emission lines EL1 to Elm may extend in the first direction DR1 and are electrically connected to the emission driver EDV.

The first voltage line PL may include a portion extending in the second direction DR2 and a portion extended in the first direction DR1. The portion extending in the first direction DR1 and the portion extending in the second direction DR2 may be disposed on different layers. The portion of the first voltage line PL extending in the second direction DR2 may extend to the second region AA2 via the bending region BDA. The first voltage line PL may provide a first voltage to the pixels PX.

The first control line CSL1 may be electrically connected to the scan driver SDV, and may extend toward a lower end (e.g., minus DR2 direction) of the second region AA2 via the bending region BDA. The second control line CSL2 may be electrically connected to the light emission driver EDV, and may extend toward the lower end of the second region AA2 via the bending region BDA.

In a plan view, the pads PD may be disposed adjacent to the lower end (i.e., minus DR2 direction) of the second region AA2. The driving chip DIC, the first voltage line PL, the first control line CSL1, and the second control line CSL2 may be electrically connected to the pads PD. The flexible circuit board FCB may be electrically connected to the pads PD through an anisotropic conductive adhesive layer.

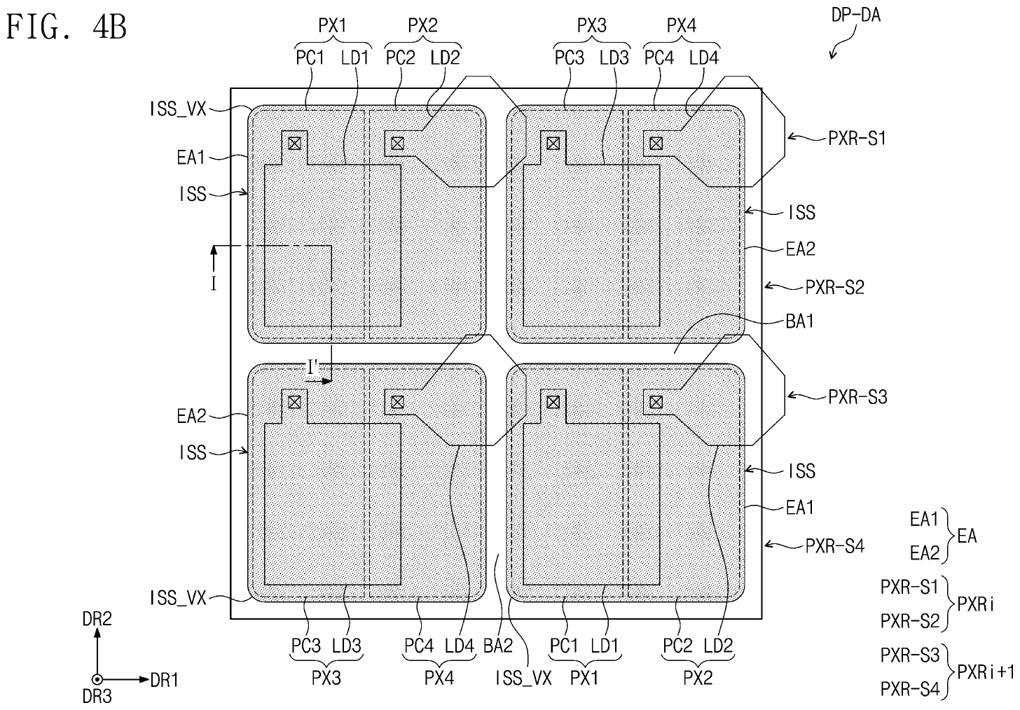

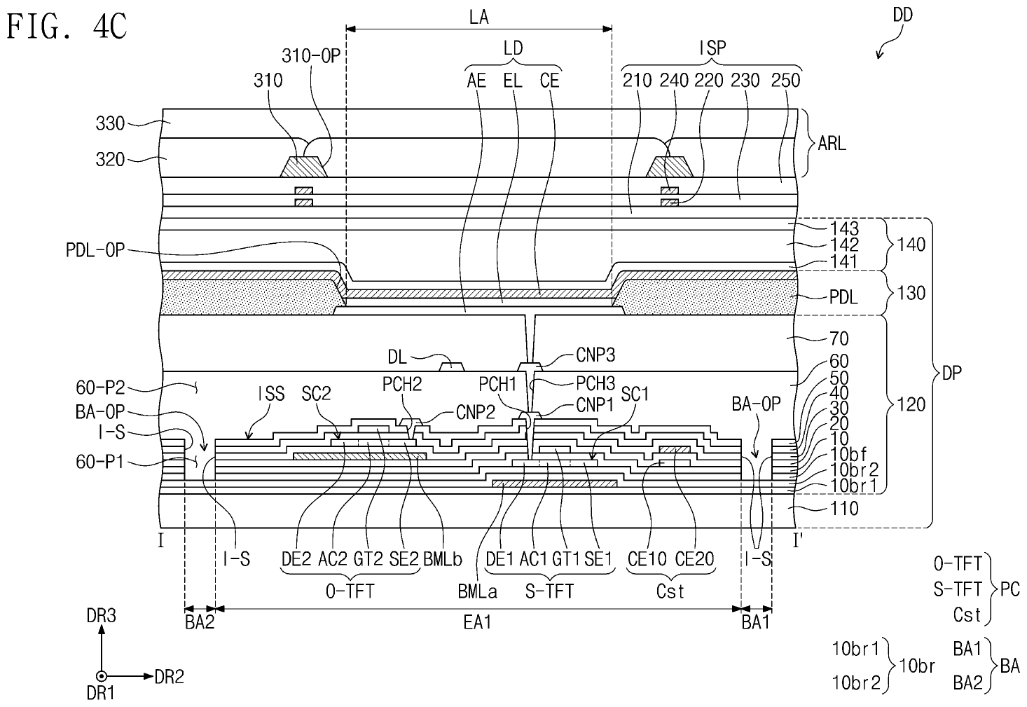

FIG. 4A is a schematic diagram of an equivalent circuit of a pixel Pxij according to an embodiment. FIG. 4B is a plan view of the display region DP-DA of the display panel DP according to an embodiment. FIG. 4C is a schematic cross-sectional view of the display module DM according to an embodiment.

FIG. 4A exemplarily illustrates a pixel Pxij electrically connected to an i-th scan line SLi among the first group of scan lines SL1 to SLm of FIG. 3, and electrically connected to a j-th data line DLj among the data lines DL1 to DLn of FIG. 3. The pixel Pxij may include a pixel driving circuit PC and a light emitting element LD.

In the embodiment, the pixel driving circuit PC may include first to seventh transistors T1 to T7 and a capacitor Cst. In the embodiment, the first transistor T1, the second transistor T2, and the fifth transistor T5 to the seventh transistor T7 may be described as P-type transistors, and the third transistor T3 and the fourth transistor T4 may be described as N-type transistors. However, the embodiment may not be limited thereto, and the first to seventh transistors T1 to T7 may be implemented as either a P-type transistor or an N-type transistor. An input region (or input electrode) of the N-type transistor may be described as a drain (or drain region), and an input region of the P-type transistor may be described as a source (or source region), an output region (or output electrode) of the N-type transistor may be described as a source (or source region), and an output region of the P-type transistor may be described as a drain (or drain region). Also, in an embodiment, at least one of the first to seventh transistors T1 to T7 may be omitted.

In the embodiment, the first transistor T1 may be a driving transistor, and the second transistor T2 may be a switching transistor. The capacitor Cst may be electrically connected between the first voltage line PL receiving a first power voltage ELVDD and a reference node RN. The capacitor Cst may include a first electrode CE10 electrically connected to the reference node RN, and a second electrode CE20 electrically connected to the first voltage line PL.

The first transistor T1 may be electrically connected between the first voltage line PL and an electrode of the light emitting element LD. A source S1 of the first transistor T1 may be electrically connected to the first voltage line PL. In the disclosure, “being electrically connected between a transistor and a signal line” or “between a transistor and a transistor” means that “a source, a drain, and a gate of the transistor have a shape of a single body with the signal line, or may be electrically connected through a connection electrode.” Between the source S1 of the first transistor T1 and the first voltage line PL, another transistor may be disposed or omitted.

A drain D1 of the first transistor T1 may be electrically connected to the anode of the light emitting element LD. Between the drain D1 of the first transistor T1 and the anode of the light emitting element LD, another transistor may be disposed or omitted. A gate G1 of the first transistor T1 may be electrically connected to the reference node RN.

The second transistor T2 may be electrically connected between the j-th data line DLj and the source S1 of the first transistor T1. A source S2 of the second transistor T2 may be electrically connected to the j-th data line DLj, and a drain D2 of the second transistor T2 may be electrically connected to the source S1 of the first transistor T1. In the embodiment, a gate G2 of the second transistor T2 may be electrically connected to the i-th scan line SLi of the first group.

The third transistor T3 may be electrically connected between the reference node RN and the drain D1 of the first transistor T1. A drain D3 of the third transistor T3 may be electrically connected to the drain D1 of the first transistor T1, and a source S3 of the third transistor T3 may be electrically connected to the reference node RN. Although the third transistor T3 may be illustrated as having a single gate, the third transistor T3 may include multiple gates. In the embodiment, a gate G3 of the third transistor T3 may be electrically connected to an i-th scan line GLi of a second group.

The fourth transistor T4 may be electrically connected between the reference node RN and a second voltage line VL1. A drain D4 of the fourth transistor T4 may be electrically connected to the reference node RN, and a source S4 of the fourth transistor T4 may be electrically connected to the second voltage line VL1. Although the fourth transistor T4 may be illustrated as having a single gate, the fourth transistor T4 may include multiple gates. In the embodiment, a gate G4 of the fourth transistor T4 may be electrically connected to an i-th scan line HLi of a third group.

The fifth transistor T5 may be electrically connected between the first voltage line PL and the source S1 of the first transistor T1. A source S5 of the fifth transistor T5 may be electrically connected to the first voltage line PL, and a drain D5 of the fifth transistor T5 may be electrically connected to the source S1 of the first transistor T1. A gate G5 of the fifth transistor T5 may be electrically connected to an i-th emission line ELi.

The sixth transistor T6 may be electrically connected between the drain D1 of the first transistor T1 and the light emitting element LD. A source S6 of the sixth transistor T6 may be electrically connected to the drain D1 of the first transistor T1, and a drain D6 of the sixth transistor T6 may be electrically connected to the anode of the light emitting element LD. A gate G6 of the sixth transistor T6 may be electrically connected to the i-th emission line ELi. In an embodiment, the gate G6 of the sixth transistor T6 may be electrically connected to a signal line different from the signal line to which the gate G5 of the fifth transistor T5 is electrically connected.

The seventh transistor T7 may be electrically connected between the drain D6 of the sixth transistor T6 and a third voltage line VL2. A source S7 of the seventh transistor T7 may be electrically connected to the drain D6 of the sixth transistor T6, and a drain D7 of the seventh transistor T7 may be electrically connected to the third voltage line VL2. A gate G7 of the seventh transistor T7 may be electrically connected to an i+1-th scan line SLi+1 of the first group. The light emitting clement LD may be connected between the source S7 of the seventh transistor T7 and the second power voltage ELVSS.

In case that an emission control signal EMi has a high level, the fifth transistor T5 and the sixth transistor T6 may be turned off. In case that the fifth transistor T5 and the sixth transistor T6 are turned off, a current path may not be formed between the first voltage line PL and the light emitting element LD. Therefore, a corresponding interval may be defined as a non-light emitting interval.

In case that a scan signal HCi applied to the i-th scan line HLi of the third group has a high level, the fourth transistor T4 may be turned on. In case that the fourth transistor T4 is turned on, the reference node RN may be initialized by a first initialization voltage Vint.

In case that a scan signal GWi applied to the i-th scan line SLi of the first group has a low level, and a scan signal GCi applied to the i-th scan line GLi of the second group has a high level, the second transistor T2 and the third transistor T3 may be turned on.

Since the reference node RN may be initialized by the initialization voltage Vint, the first transistor T1 may be in the state of being turned on. In case that the first transistor T1 is turned on, a voltage corresponding to a data signal Dj may be provided to the reference node RN. At this time, the capacitor Cst may store the voltage corresponding to the data signal Dj. The voltage corresponding to the data signal Dj may be a voltage reduced by a threshold voltage Vth of the first transistor T1 from the data signal Dj.

In case that a scan signal GWi+1 applied to the i+1-th scan line SLi+1 of the first group has a low level, the seventh transistor T7 may be turned on. As the seventh transistor T7 is turned on, the anode of the light emitting element LD may be initialized by a second initialization voltage VAint. A parasitic capacitor of the light emitting element LD may be discharged.

In case that the emission control signal EMi has a low level, the fifth transistor T5 and the sixth transistor T6 may be turned on. In case that the fifth transistor T5 is turned on, the first power voltage ELVDD may be provided to the first transistor T1. In case that the sixth transistor T6 is turned on, the first transistor T1 and the light emitting element LD may be electrically connected. The light emitting element LD generates light of luminance corresponding to the amount of received current.

FIG. 4B illustrates an enlarged portion of the display region DP-DA corresponding to two pixel rows PXRi and PXRi+1. The display region DP-DA may be the first display region DA1 or the second display region DA2 illustrated in FIG. 3.

The display region DP-DA may include multiple element regions EA and a boundary region BA adjacent to the element regions EA. The multiple element regions EA may include a first-type element region EA1 and a second-type element region EA2. The first-type element region EA1 and the second-type element region EA2 may be alternately disposed along the first direction DR1, and the first-type element region EA1 and the second-type element region EA2 may be alternately disposed along the second direction DR2.

The boundary region BA may surround each of the first-type element region EA1 and the second-type element region EA2. The boundary region BA may include first boundary regions BA1 extending in the first direction DR1 and second boundary regions BA2 extending in the second direction DR2. The first boundary regions BA1 and the second boundary regions BA2 may intersect at multiple points. In the embodiment, “the first boundary regions BA1 extending in the first direction DR1” may not be limited to the first boundary regions BA1 having a same width. In a region between the first-type element region EA1 and the second-type element region EA2, the width of the first boundary regions BA1 in the second direction DR2 may be uniform, but the embodiment may not be necessarily limited thereto.

The boundary region BA may be defined by an opening formed in multiple inorganic layers. The boundary region BA will be described in detail later.

An i-th pixel row PXRi may include a first pixel PX1, a second pixel PX2, a third pixel PX3, and a fourth pixel PX4 arranged in the first direction DR1. The first pixel PX1, the second pixel PX2, the third pixel PX3, and the fourth pixel PX4 may be repeating units in the i-th pixel row PXRi. The first pixel PX1, the second pixel PX2, the third pixel PX3, and the fourth pixel PX4 may respectively include pixel driving circuits PC1, PC2, PC3, and PC4 and light emitting elements LD1, LD2, LD3, and LD4 electrically connected to the pixel driving circuits PC1, PC2, PC3, and PC4. The pixel driving circuits PC1, PC2, PC3, and PC4 may be the pixel driving circuit PC of FIG. 4A. FIG. 4B illustrates anodes of the light emitting elements LD1, LD2, LD3, and LD4 as representatives of the light emitting elements LD1, LD2, LD3, and LD4. FIG. 4B illustrates that an anode of the first pixel PX1 and an anode of the third pixel PX3 have a same shape and a same area, and an anode of the second pixel PX2 and an anode of the fourth pixel PX4 have a same shape and a same area, but the embodiment may not be limited thereto.

The first pixel PX1 may generate first color light, and the first color light may be red light. The second pixel PX2 and the fourth pixel PX4 may each generate second color light, and the second color light may be green light. The third pixel PX3 may generate third color light, and the third color light may be blue light. In the embodiment, it may be described that two pixels generating different light may be disposed in each of the element regions EA, but the embodiment may not be necessarily limited thereto.

The first pixel PX1 and the second pixel PX2 may be disposed corresponding to the first-type element region EA1, and the third pixel PX3 and the fourth pixel PX4 may be disposed corresponding to the second-type element region EA2. The pixel driving circuit PC1 (hereinafter, a first pixel driving circuit) of the first pixel PX1 and the pixel driving circuit PC2 (hereinafter, a second pixel driving circuit) of the second pixel PX2 may overlap the first-type element region EA1. The first pixel driving circuit PC1 and the second pixel driving circuit PC2 may be disposed in different regions of the first-type element region EA1. A region in which the first pixel driving circuit PC1 may be disposed may be defined as a first pixel region, and a region in which the second pixel driving circuit PC2 may be disposed may be defined as a second pixel region. FIG. 4B exemplarily illustrates a first pixel region and a second pixel region having a shape in which the first-type element region EA1 may be partitioned with respect to the second direction DR2, but the embodiment may not be limited thereto. Since a pixel region may be a region in which a pixel driving circuit may be substantially disposed, the boundary between the first pixel region and the second pixel region may not be limited to a straight line.

The pixel driving circuit PC3 (hereinafter, a third pixel driving circuit) of the third pixel PX3 and the pixel driving circuit PC4 (hereinafter, a fourth pixel driving circuit) of the fourth pixel PX4 may overlap the second-type element region EA2. The third pixel driving circuit PC3 and the fourth pixel driving circuit PC4 may be disposed in different regions of the second-type element region EA2. A region in which the third pixel driving circuit PC3 may be disposed may be defined as a third pixel region, and a region in which the fourth pixel driving circuit PC4 may be disposed may be defined as a fourth pixel region.

The light emitting element LD2 of the second pixel PX2 and the light emitting clement LD4 of the fourth pixel PX4 may be aligned in the first direction DR1 to define a first sub-pixel row PXR-S1, and the light emitting element LD1 (hereinafter, a first light emitting element) of the first pixel PX1 and the light emitting element LD3 (hereinafter, a third light emitting element) of the third pixel PX3 may be aligned in the first direction DR1 to define a second sub-pixel row PXR-S2. An anode of the second light emitting element LD2 and an anode of the fourth light emitting element LD4 may partially overlap the boundary region BA. However, the second pixel driving circuit PC2 and the fourth pixel driving circuit PC4 do not overlap the boundary region BA. That is, a silicon transistor S-TFT and an oxide transistor O-TFT, will be described later, do not overlap the boundary region BA.

The i+1-th pixel row PXRi+1 may include the third pixel PX3, the fourth pixel PX4, the first pixel PX1, and the second pixel PX2 arranged in the first direction DR1. The second light emitting element LD2 and the fourth light emitting element LD4 may be aligned in the first direction DR1 to define a third sub-pixel row PXR-S3, and the third light emitting element LD3 and the first light emitting element LD1 may be aligned in the first direction DR1 to define a fourth sub-pixel row PXR-S4.

As illustrated in FIG. 4C, the display module DM may include the display panel DP, an input sensor ISP disposed on the display panel DP, and an anti-reflection layer ARL disposed on the input sensor ISP.

Referring to FIG. 4C, the pixel driving circuit PC may include multiple transistors and a capacitor. FIG. 4C illustrates the silicon transistor S-TFT and the oxide transistor O-TFT as examples of transistors. FIG. 4C illustrates some components of the pixel driving circuit PC illustrated in FIG. 4A. In an embodiment, the pixel driving circuit PC may include only one type of transistor between the silicon transistor S-TFT and the oxide transistor O-TFT.

Referring to FIG. 4C, a base layer 110 may be illustrated as a single layer. The base layer 110 may include a synthetic resin such as polyimide. A synthetic resin layer may be coated on a work substrate to form the base layer 110. In case that the display module DM may be completed by proceeding with a subsequent process, the work substrate may be removed. The base layer 110 may have a multi-layered structure of a first synthetic resin layer, an inorganic layer, and a second synthetic resin layer.

Referring to FIG. 4C, a barrier layer 10br may be disposed on the base layer 110. The barrier layer 10br may prevent foreign substances from being introduced from the outside. The barrier layer 10br may include at least one inorganic layer. The barrier layer 10br may include a silicon oxide layer, a silicon nitride layer, or a combination thereof. Each of these layers may be provided in plurality, and the silicon oxide layers and the silicon nitride layers may be alternately stacked on each other.

The barrier layer 10br may include a lower barrier layer 10br1 and an upper barrier layer 10br2. Between the lower barrier layer 10br1 and the upper barrier layer 10br2, a first shielding electrode BMLa may be disposed. The first shielding electrode BMLa may be disposed to correspond to the silicon transistor S-TFT. The first shielding electrode BMLa may include a metal.

The first shielding electrode BMLa may receive a bias voltage. The first shielding electrode BMLa may receive a first power voltage. The first shielding electrode BMLa may stop an electrical potential due to polarization from affecting the silicon transistor S-TFT. The first shielding electrode BMLa may stop external light from reaching the silicon transistor S-TFT. In an embodiment, the first shielding electrode BMLa may be a floating electrode in an isolated form from another electrode or line.

A buffer layer 10bf may be disposed on the barrier layer 10br. The buffer layer 10bf may prevent a phenomenon in which metal atoms or impurities diffuse from the base layer 110 into a first semiconductor pattern SC1 on an upper side. The buffer layer 10bf may include at least one inorganic layer. The buffer layer 10bf may include a silicon oxide layer, a silicon nitride layer, or a combination thereof.

On the buffer layer 10bf, the first semiconductor pattern SC1 may be disposed. The first semiconductor pattern SC1 may include a silicon semiconductor. For example, the silicon semiconductor may include amorphous silicon, polycrystalline silicon, the like, or a combination thereof. For example, the first semiconductor pattern SC1 may include low-temperature polysilicon.

The first semiconductor pattern SC1 may have different electrical properties depending on whether or not it is doped. The first semiconductor pattern SC1 may include a first region having high conductivity and a second region having low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region, or a region doped to a concentration lower than that of the first region. In the embodiment, the first semiconductor pattern SC1 may be the N-type transistor.

The conductivity of the first region may be greater than the conductivity of the second region, and the first region may substantially serve as an electrode or a signal line. The second region may substantially correspond to a channel region (or active region) of a transistor. In other words, a portion of the first semiconductor pattern SC1 may be a channel of a transistor, and another portion thereof may be a source or a drain of the transistor, and the other portion thereof may be a connection electrode or a connection signal line.

A source region SE1, a channel region AC1 (or active region), and a drain region DE1 of the silicon transistor S-TFT may be formed from the first semiconductor pattern SC1. The source region SE1 and the drain region DE1 may extend in opposite directions from the channel region AC1 in a cross-sectional view.

On the buffer layer 10bf, a first insulation layer 10 may be disposed. The first insulation layer 10 may cover the first semiconductor pattern SC1. The first insulation layer 10 may be an inorganic layer. The first insulation layer 10 may be a single-layered silicon oxide layer. The first insulation layer 10 as well as an inorganic layer of a driving element layer 120 to be described later may have a single-layered or multi-layered structure, and may include at least one of the above-described materials, but the embodiment may not be limited thereto.

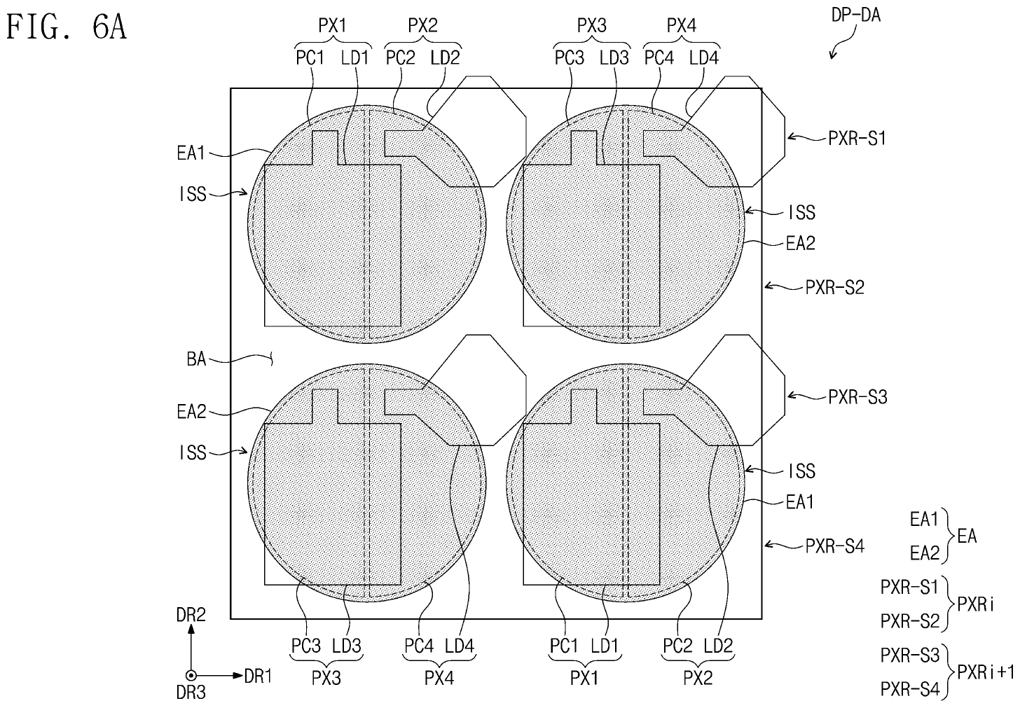

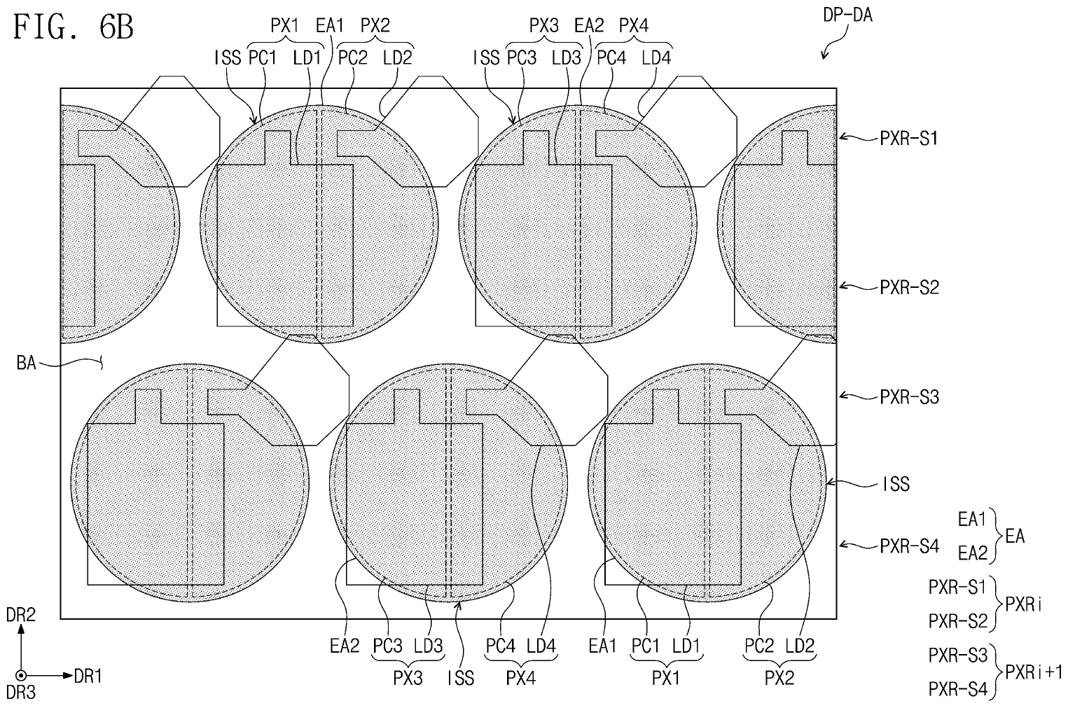

On the first insulation layer 10, a gate GT1 of the silicon transistor S-TFT may be disposed. The gate GT1 may be a portion of a metal pattern. The gate GT1 overlaps the channel region AC1. In a process of doping the first semiconductor pattern SC1, the gate GT1 may be a mask. On the first insulation layer 10, a first electrode CE10 of a storage capacitor Cst may be disposed. Unlike what is illustrated in FIG. 6, the first electrode CE10 may have a shape of a single body with the gate GT1.

A second insulation layer 20 may be disposed on the first insulation layer 10, and may cover the gate GT1. In an embodiment, on the second insulation layer 20, an upper electrode overlapping the gate GT1 may be further disposed. On the second insulation layer 20, a second electrode CE20 overlapping the first electrode CE10 may be disposed. The upper electrode may have a shape of a single body in a plan view with the second electrode CE20.

On the second insulation layer 20, a second shielding electrode BMLb may be disposed. The second shielding electrode BMLb may be disposed to correspond to the oxide transistor O-TFT. In an embodiment, the second shielding electrode BMLb may be omitted. According to an embodiment, the first shielding electrode BMLa may extend to a lower portion of the oxide transistor O-TFT to replace the second shielding electrode BMLb.

On the second insulation layer 20, a third insulation layer 30 may be disposed. A second semiconductor pattern SC2 may be disposed on the third insulation layer 30. The second semiconductor pattern SC2 may include a channel region AC2 of the oxide transistor O-TFT. The second semiconductor pattern SC2 may include an oxide semiconductor. The second semiconductor pattern SC2 may include a transparent conductive oxide (TCO) such as an indium tin oxide (ITO), an indium zinc oxide (IZO), an indium gallium zinc oxide (IGZO), a zinc oxide (ZnOₓ), an indium oxide (In₂O₃), the like, or a combination thereof.

The oxide semiconductor may include multiple regions SE2, AC2, and DE2 which may be distinguished depending on whether the transparent conductive oxide has been reduced or not. A region in which the transparent conductive oxide has been reduced (hereinafter, a reduction region) has conductivity greater than that of a region in which the transparent conductive oxide has not been reduced (hereinafter, a non-reduction region). The reduction region substantially serves as a source/drain or signal line of a transistor. The non-reduction region substantially corresponds to a semiconductor region (or channel) of a transistor. In other words, a partial region of the second semiconductor pattern SC2 may be a semiconductor region of a transistor, another partial region thereof may be a source region SE2/a drain region DE2 of the transistor, and the other partial region thereof may be a signal transmission region.

On the third insulation layer 30, a fourth insulation layer 40 may be disposed. As illustrated in FIG. 6, the fourth insulation layer 40 may cover the second semiconductor pattern SC2. In an embodiment, the fourth insulation layer 40 may overlap a gate GT2 of the oxide transistor O-TFT, and may be an insulation pattern exposed by the source region SE2 and the drain region DE2 of the oxide transistor O-TFT.

On the fourth insulation layer 40, the gate GT2 of the oxide transistor O-TFT may be disposed. The gate GT2 of the oxide transistor O-TFT may be a portion of a metal pattern. The gate GT2 of the oxide transistor O-TFT may overlap a channel region AC2.

On the fourth insulation layer 40, a fifth insulation layer 50 may be disposed, and the fifth insulation layer 50 may cover the gate GT2 of the oxide transistor O-TFT. The first insulation layer 10 to the fifth insulation layer 50 may each be an inorganic layer. As described above, the pixel driving circuit PC may be formed between the base layer 110 and the fifth insulation layer 50, or may be formed between the base layer 110 and a sixth insulation layer 60 to be described layer.

An opening BA-OP defining the boundary region BA may be formed in at least some of inorganic layers of a stacked structure from the barrier layer 10br to the fifth insulation layer 50. The opening BA-OP may form a valley on the display panel DP. In the embodiment, the opening BA-OP may pass through the buffer layer 10bf to the fifth insulation layer 50. However, the embodiment may not be limited thereto, and the inorganic layers in which the opening BA-OP may be formed may be changed. For example, the opening BA-OP may be formed up to the barrier layer 10br, or may pass through to an upper barrier layer 10br2 in the barrier layer 10br. As to be described later, the opening BA-OP may be formed to prevent a crack in an inorganic layer, and thus passes through most of the inorganic layers from the barrier layer 10br to the fifth insulation layer 50.

In the embodiment, the stacked structure in which the opening BA-OP is disposed may be defined as an inorganic stacked structure ISS. In the embodiment, the inorganic stacked structure ISS may be a stacked structure of the buffer layer 10bf to the fifth insulation layer 50. The inorganic stacked structure ISS may be an island structure.

The opening BA-OP has a shape corresponding to the boundary region BA of FIG. 4B in a plan view. The opening BA-OP may suppress the generation of cracks in an inorganic layer by partitioning the inorganic layers, which may be entirely stacked in the display region DP-DA, into multiple islands. Since an impact applied from the outside may be concentrated at the opening BA-OP, it may be possible to prevent cracks from forming in a stacked structure of inorganic materials. The opening BA-OP may also prevent cracks already formed in a specific element region EA (see FIG. 4B) from expanding to an adjacent element region EA.

A first connection pattern CNP1 and a second connection pattern CNP2 may be disposed on the fifth insulation layer 50. The first connection pattern CNP1 may be electrically connected to the drain region DE1 of the silicon transistor S-TFT through a first contact-hole PCH1 passing through the first to fifth insulation layers 10, 20, 30, 40, and 50, and the second connection pattern CNP2 may be electrically connected to the source region SE2 of the oxide transistor O-TFT through a second contact-hole PCH2 passing through the first to fifth insulation layers 10, 20, 30, 40, and 50.

The sixth insulation layer 60 may be disposed inside the opening BA-OP, and may be disposed on the fifth insulation layer 50. The sixth insulation layer 60 may include a first portion 60-P1 in contact with the inorganic stacked structure ISS in the opening BA-OP and a second portion 60-P2 disposed on the fifth insulation layer 50.

A third connection pattern CNP3 may be disposed on the sixth insulation layer 60. The third connection pattern CNP3 may be electrically connected to the first connection pattern CNP1 through a third contact-hole PCH3 passing through the sixth insulation layer 60. On the sixth insulation layer 60, a data line DL may be disposed. The data line DL may overlap the element regions EA and the boundary region BA illustrated in FIG. 4B. This may be because the data line DL crosses the display region DP-DA in the second direction DR2 as illustrated in FIG. 3.

A seventh insulation layer 70 may be disposed on the sixth insulation layer 60, and may cover the third connection pattern CNP3 and the data line DL. The third connection pattern CNP3 and the data line DL may be formed through a same process, and thus may have a same material and a same stacking structure. The sixth insulation layer 60 and the seventh insulation layer 70 may each be an organic layer.

A display element layer 130 is disposed on the driving element layer 120. The display element layer 130 includes a light emitting element LD and a pixel definition film PDL. The light emitting element LD may include an anode AE (or a first electrode), a light emitting layer EL, and a cathode CE (or a second electrode). The anode AE of the light emitting element LD may be disposed on the seventh insulation layer 70. The anode AE may be a semi-transmissive electrode or a reflective electrode. The anode AE may include a stacked structure of ITO/Ag/ITO. Positions of the anode AE and the cathode CE may be interchanged.

A pixel definition film PDL may be disposed on the seventh insulation layer 70. The pixel definition film PDL may be an organic layer. The pixel definition film PDL may have properties of absorbing light, and for example, the pixel definition film PDL may have a black color. The pixel definition film PDL may include a black coloring agent. The black coloring agent may include a black dye and a black pigment. The black coloring agent may include carbon black, a metal such as chromium, an oxide thereof, or a combination thereof. The pixel definition film PDL may correspond to a light blocking pattern having light blocking properties.

The pixel definition film PDL may cover a portion of the anode AE. For example, an opening PDL-OP exposing a portion of the anode AE may be defined in the pixel definition film PDL. A light emitting region LA may be defined to correspond to the opening PDL-OP. In an embodiment, a hole control layer may be disposed between the anode AE and the light emitting layer EL. The hole control layer includes a hole transport layer, and may further include a hole injection layer. An electron control layer may be disposed between the light emitting layer EL and the cathode CE. The electron control layer includes an electron transport layer, and may further include an electron injection layer.

An encapsulation layer 140 may cover the light emitting element LD. The encapsulation layer 140 may include an encapsulation inorganic layer 141, an encapsulation organic layer 142, and an encapsulation inorganic layer 143 which may be sequentially stacked on each other, but layers constituting the encapsulation layer 140 may not be necessarily limited thereto. The encapsulation inorganic layers 141 and 143 may include a silicon nitride layer, a silicon oxynitride layer, a silicon oxide layer, a titanium oxide layer, an aluminum oxide layer, the like, or a combination thereof. The encapsulation inorganic layers 141 and 143 may each have a multi-layered structure. The encapsulation organic layer 142 may include, but may not be limited to, an acrylic-based organic layer.

The input sensor ISP may be disposed on the display panel DP. The input sensor ISP may include at least one conductive layer and at least one insulation layer. In the embodiment, the input sensor ISP may include a first insulation layer 210, a first conductive layer 220, a second insulation layer 230, a second conductive layer 240, and a third insulation layer 250. At least one of the first insulation layer 210 and the third insulation layer 250 may be omitted.

The first insulation layer 210 may be disposed (e.g., directly disposed) on the display panel DP. The first insulation layer 210 may be an inorganic layer including at least one of a silicon nitride, a silicon oxynitride, or a silicon oxide. The first conductive layer 220 and the second conductive layer 240 may each have a single-layered structure, or may have a multi-layered structure in which multiple layers may be stacked on each other along the third direction DR3. The first conductive layer 220 and the second conductive layer 240 may include conductive lines which define an electrode of a mesh shape. A conductive line of the first conductive layer 220 and a conductive line of the second conductive layer 240 may be electrically connected though a contact-hole passing through the second insulation layer 230, or might not be electrically connected. Depending on the type of a sensor provided as the input sensor ISP, the connection relationship between the conductive line of the first conductive layer 220 and the conductive line of the second conductive layer 240 may be determined.

The first conductive layer 220 and the second conductive layer 240, which have a single-layered structure, may include a metal layer or a transparent conductive layer. The metal layer may include molybdenum, silver, titanium, copper, aluminum, an alloy thereof, or a combination thereof. The transparent conductive layer may include a transparent conductive oxide such as an indium tin oxide (ITO), an indium zinc oxide (IZO), a zinc oxide (ZnOₓ), an indium tin zinc oxide (ITZO), the like, or a combination thereof. The transparent conductive layer may include a conductive polymer such as PEDOT, a metal nanowire, graphene, the like, or a combination thereof.

The first conductive layer 220 and the second conductive layer 240, which have a multi-layered structure, may include metal layers. The metal layers may have, for example, a three-layered structure of titanium/aluminum/titanium. A conductive layer of a multi-layered structure may include at least one metal layer and at least one transparent conductive layer. The second insulation layer 230 may be disposed between the first conductive layer 220 and the second conductive layer 240.

The anti-reflection layer ARL may be disposed on the input sensor ISP. The anti-reflection layer ARL may include a partition layer 310, a color filter 320, and a planarization layer 330.

A material constituting the partition layer 310 may not be particularly limited as long as it is a material which absorbs light. The partition layer 310 may be a layer having a black color, and in an embodiment, the partition layer 310 may include a black coloring agent. The black coloring agent may include a black dye and a black pigment. The black coloring agent may include carbon black, a metal such as chromium, an oxide thereof, or a combination thereof.

The partition layer 310 may cover the second conductive layer 240 of the input sensor ISP. The partition layer 310 may prevent external light reflection off of the second conductive layer 240. An opening 310-OP may be defined in the partition layer 310. The opening 310-OP may overlap the anode AE.

The color filter 320 may overlap the opening 310-OP. The color filter 320 may overlap the light emitting element LD1 on a lower side. The color filter 320 may come into contact with the partition layer 310.

The planarization layer 330 may cover the partition layer 310 and the color filter 320. The planarization layer 330 may include an organic material, and an approximately flat surface may be provided on an upper surface of the planarization layer 330. In an embodiment, the planarization layer 330 may be omitted.

Referring to FIG. 4B and FIG. 4C, the inorganic stacked structure ISS may be disposed in each of the element regions EA. The stacked structure of the buffer layer 10bf to the fifth insulation layer 50 may be included in the inorganic stacked structures ISS disposed in each of the element regions EA. The inorganic stacked structures ISS may be disposed spaced apart from each other with the boundary region BA disposed therebetween.

Referring to FIG. 4B and FIG. 4C, the opening BA-OP may be defined by an inner surface I-S of the inorganic stacked structure ISS. The inner surface I-S of the inorganic stacked structure ISS defines a substantially polygonal shape including a vertex (or corner) region ISS_VX having an outwardly convex curve in a plan view. Accordingly, the area of the opening BA-OP increases at an intersection region of the first boundary regions BA1 and the second boundary regions BA2.

The inorganic stacked structure ISS may have a substantially polygonal shape in a plan view. In the specification, the “substantial polygonal shape” means including a vertex region having an outwardly convex curve instead of a sharp-cornered vertex in the mathematical sense. The inorganic stacked structure ISS includes a vertex region having a convex curve in a plan view, and thus disperses stress generated in the vertex region. Referring to FIG. 4B, in the embodiment, the inorganic stacked structure ISS may be a substantially square shape.

In case that an external impact may be applied to a display panel through a pen drop experiment, it can be confirmed that cracks may be substantially more readily generated at the vertex of the inorganic stacked structure ISS. The crack at the vertex may propagate in a horizontal direction and cause defects in the inorganic stacked structure ISS. The vertex region having a convex curve may disperse stress, thereby suppressing the generation of cracks.

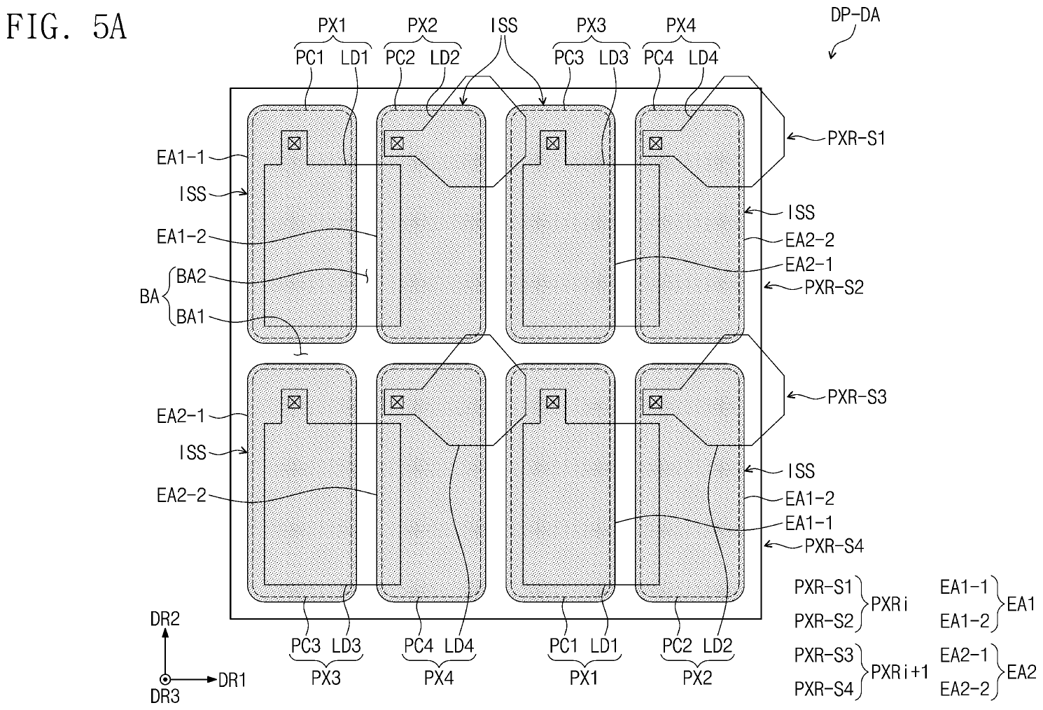

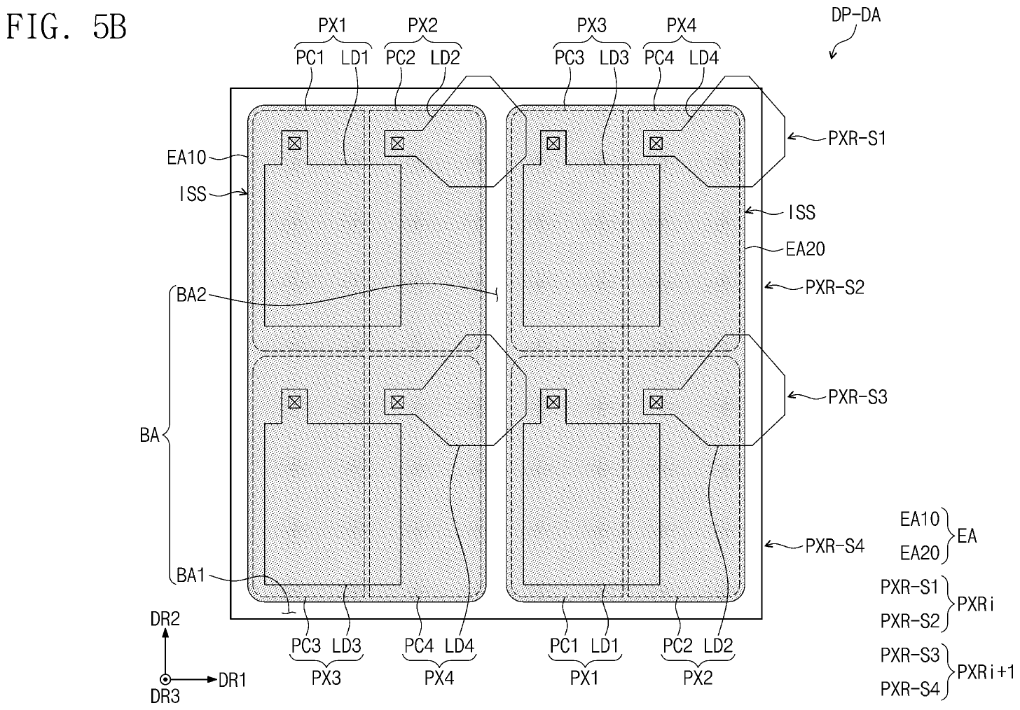

FIG. 5A and FIG. 5B are plan views of the display region DP-DA of the display panel DP (see FIG. 3) according to an embodiment. Hereinafter, for detailed descriptions of the same components as those described with reference to FIG. 4A to FIG. 4C, refer to FIG. 4A to FIG. 4C.

Referring to FIG. 5A, unlike FIG. 4B, the first-type element region EA1 may be partitioned into a first partial element region EA1-1 and a second partial element region EA1-2 by a second boundary region BA2, and the second-type element region EA2 may be partitioned into a third partial element region EA2-1 and a fourth partial element region EA2-2 by a second boundary region BA2. The inorganic stacked structure ISS described with reference to FIG. 4C may be disposed in each of the first partial element region EA1-1, the second partial element region EA1-2, the third partial element region EA2-1, and the fourth partial element region EA2-2.

The first to fourth light emitting elements LD1, LD2, LD3, and LD4 may overlap the boundary region BA. As described with reference to FIG. 4C, the first to fourth light emitting elements LD1, LD2, LD3, and LD4 may be disposed on the seventh insulation layer 70, so that the boundary region BA does not limit the design of the first to fourth light emitting elements LD1, LD2, LD3, and LD4.

Referring to FIG. 5B, unlike FIG. 4B, in a first-type element region EA10, the first pixel PX1 and the second pixel PX2 of the i-th pixel row PXRi and the third pixel PX3 of the fourth pixel PX4 of the i+1-th pixel row PXRi+1 may be disposed. In a second-type element region EA20, the third pixel PX3 and the fourth pixel PX4 of the i-th pixel row PXRi and the first pixel PX1 of the second pixel PX2 of the i+1-th pixel row PXRi+1 may be disposed. The inorganic stacked structure ISS may be disposed in each of the first-type element region EA10 and the second-type element region EA20.

FIG. 6A and FIG. 6B are plan views of the display region DP-DA of the display panel DP (see FIG. 3) according to an embodiment. Hereinafter, for detailed descriptions of the same components as those described with reference to FIG. 4A to FIG. 4C, refer to FIG. 4A to FIG. 4C.

Referring to FIG. 6A, the inorganic stacked structure ISS may have a circular shape in a plan view. Since the inorganic stacked structure ISS has a circular shape, stress occurring in the inorganic stacked structure ISS may be more widely dispersed. Since a circular shape does not include a straight line portion present in a substantially polygonal shape, fewer cracks may be generated than in the inorganic stacked structure ISS of FIG. 4B.

The boundary region BA according to the embodiment surrounds each of the first-type element region EA10 and the second-type element region EA20, and has a wider region than the boundary region BA of FIG. 4B.

Referring to FIG. 6B, unlike FIG. 6A, the inorganic stacked structure ISS of the i-th pixel row PXRi and the inorganic stacked structure ISS of the i+1-th pixel row PXRi+1 may be disposed staggered from each other. Accordingly, the area of the boundary region BA of FIG. 6B may be reduced compared to that of the boundary area BA of FIG. 6A. The ratio of the area occupied by the element region EA to an area occupied by the boundary area BA may be increased.

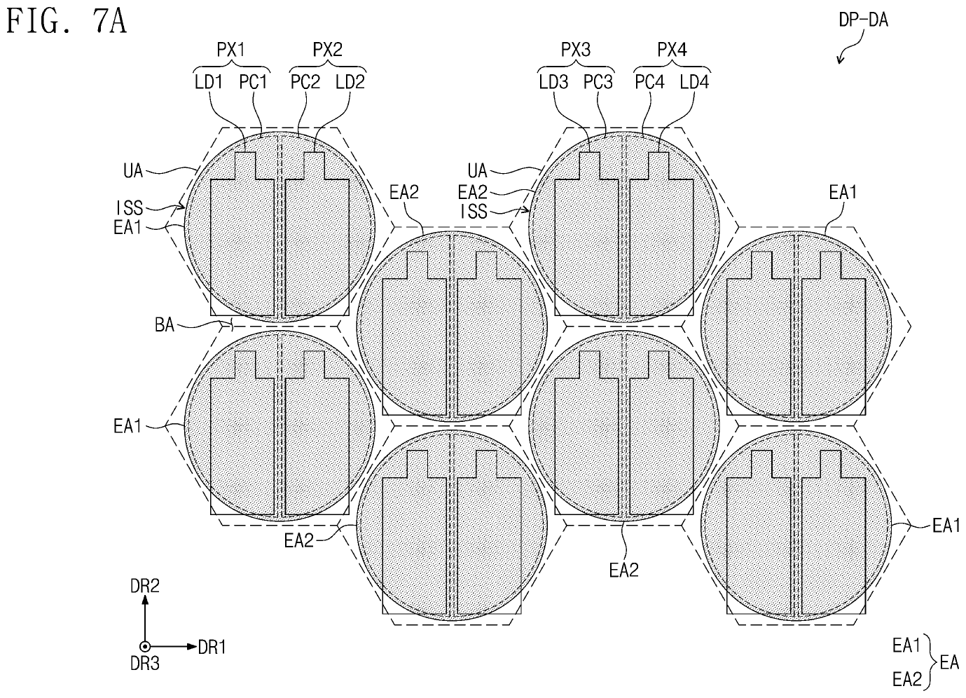

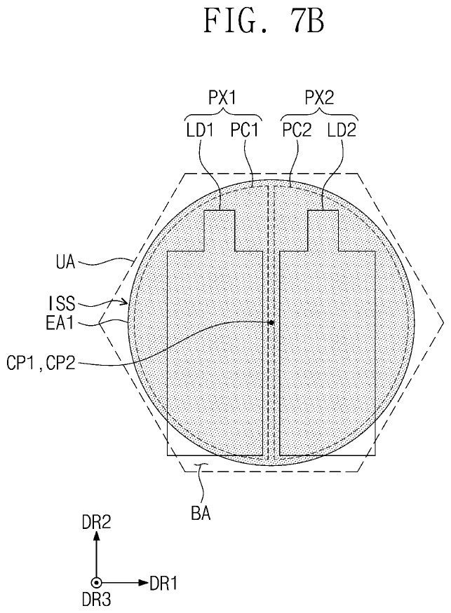

FIG. 7A is a plan view of the display region DP-DA of the display panel DP (see FIG. 3) according to an embodiment. FIG. 7B is a plan view of one enlarged unit region UA. Hereinafter, for detailed descriptions of the same components as those described with reference to FIG. 4A to FIG. 4C and FIG. 6A and FIG. 6B, refer to FIG. 4A to FIG. 4C and FIG. 6A and FIG. 6B.

Referring to FIG. 7A, the display region DP-DA may be divided into multiple unit regions UA, each of which has a cubic (or hexagonal) shape. The unit regions UA have the same area, and may have the same shape. The unit regions UA may have a honeycomb arrangement.

The element regions EA may be disposed in a one-to-one correspondence with the unit regions UA. Each of the unit regions UA may include a corresponding element region EA and a boundary region BA surrounding the element region EA. Each of the element regions EA may have a circular shape.

Referring to FIG. 7B, a center CP1 of unit region UA and a center CP2 of an element region EA may coincide. In FIG. 7B, the first element region EA1 may be illustrated as an example of the element region EA. The unit region UA may further include a portion of the boundary region BA disposed around the element region EA.

Referring to FIG. 7A and FIG. 7B, since the unit regions UA have a honeycomb (or hexagonal) arrangement, the number of unit regions UA disposed in the display region DP-DA may be increased, and the area of the element region EA disposed in each of the unit regions UA may be increased. The circular element region EA disposed in FIG. 6A may occupy up to about 78.5% of the area of the display region DP-DA. In comparison, the circular element region EA disposed in FIG. 7A may occupy up to about 90.7% of the area of the display region DP-DA.

In order to prevent a minimum distance between adjacent circular element regions EA from being smaller than a reference value, the area of the circular element region EA may be reduced. In case that the minimum distance between the adjacent circular element regions EA may be reduced, it means that the area of an organic layer disposed between element regions may be reduced, and as a result, the rate of absorbing an external impact may be reduced. Accordingly, it is preferable that the minimum distance between the circular element regions EA may be greater than or equal to the reference value.

The diameter of the circular element regions EA may be set such that the circular element regions EA disposed in FIG. 7A may occupy an area of the display region DP-DA in a range of about 80% to about 90%. Accordingly, the area of relatively circular element regions EA may be secured, and at the same time, the minimum distance between adjacent circular element regions EA may be secured to be greater than or equal to the reference value.

According to the above description, openings defined in at least some of inorganic layers of the inorganic layers may form a valley on a display panel to divide a stacked structure of the inorganic layers into island structures. The valley may improve the flexibility of the display panel and the impact resistance thereof.

A shape of the stacked structure of the inorganic layers in a plan view may be substantially polygonal or circular. A vertex region having an outwardly convex curve in a plan view may disperse stress. Cracks generated in the stacked structure of the inorganic layers in the vertex region may decrease.

Multiple element regions and a boundary region may be divided into multiple unit regions, each of which has a cubic shape in a plan view. The multiple element regions and the multiple unit regions may have a one-to-one correspondence, and since the center of the cubic shape and the center of the circular shape coincide, the area of the element region may be increased, and the area of the boundary region may be reduced.

Although the disclosure has been described with reference to embodiments of the invention, it will be understood by those skilled in the art that various modifications and changes in form and details may be made therein without departing from the spirit and scope of the disclosure as set forth in the following claims.

Accordingly, the technical scope of the disclosure may not be intended to be limited to the contents set forth in the detailed description of the embodiments, but may be intended to be defined by the appended claims.

What is claimed is:

1. A display device comprising:
a base layer including a plurality of element regions and a boundary region adjacent to the plurality of element regions;
a plurality of inorganic layers disposed on the base layer and including an opening defined in at least some of the inorganic layers, the opening corresponding to the boundary region;
an organic layer disposed inside the opening and disposed on the plurality of inorganic layers;
a pixel driving circuit disposed between the base layer and the organic layer and disposed in each of the plurality of element regions; and
a light emitting element disposed on the organic layer and electrically connected to the pixel driving circuit, wherein
the at least some of the inorganic layers include an inorganic stacked structure defined by the opening and disposed in each of the plurality of element regions,
the opening surrounds the inorganic stacked structure in a plan view,
the inorganic stacked structure has a substantially polygonal shape in a plan view and includes a corner region, and
the corner region having a shape selected from an outwardly convex curve shape and a circular shape in a plan view.

2. The display device of claim 1, wherein the inorganic stacked structure has a substantially square shape in a plan view.

3. The display device of claim 1, wherein
each of the plurality of element regions comprises a first pixel region and a second pixel region,
the pixel driving circuit includes a first pixel driving circuit and a second pixel driving circuit respectively disposed in the first pixel region and the second pixel region, and
the light emitting element includes a first light emitting element and a second light emitting element respectively electrically connected to the first pixel driving circuit and the second pixel driving circuit.

4. The display device of claim 3, wherein
the plurality of element regions comprise a first-type element region and a second-type element region,
the first light emitting element corresponding to the first-type element region and the first light emitting element corresponding to the second-type element region generate light of different colors, and
the second light emitting element corresponding to the first-type element region and the second light emitting element corresponding to the second-type element region generate light of a same color.

5. The display device of claim 4, wherein
the plurality of element regions define a plurality of rows, and
the first-type element region and the second-type element region are alternately disposed in each of the plurality of rows.

6. The display device of claim 1, wherein the light emitting element overlaps the opening in a plan view.

7. The display device of claim 6, wherein the pixel driving circuit comprises a transistor electrically connected to the light emitting element, wherein the transistor does not overlap the opening in a plan view.

8. The display device of claim 7, further comprising a data line electrically connected to the transistor, wherein the data line overlaps the opening.

9. The display device of claim 8, wherein the data line is disposed on the organic layer.

10. The display device of claim 7, wherein
the transistor comprises a silicon transistor including a silicon semiconductor pattern and an oxide transistor including an oxide transistor pattern, and
the silicon semiconductor pattern and the oxide semiconductor pattern are disposed on different ones of the plurality of inorganic layers.

11. The display device of claim 1, further comprising:
a thin film encapsulation layer covering the light emitting element;
an input sensor disposed on thin film encapsulation layer; and
a color filter disposed on the input sensor and overlapping the light emitting element in a plan view.

12. The display device of claim 1, wherein the display device is capable of being folded or rolled on a roller.

13. The display device of claim 1, wherein each of the plurality of element regions is completely surrounded by the boundary region in a plan view.

14. A display device comprising:
a base layer including a plurality of element regions and a boundary region adjacent to the plurality of element regions;
a plurality of inorganic layers disposed on the base layer and including an opening defined in at least some of the inorganic layers, the opening corresponding to the boundary region, wherein the opening surrounds at least a first element region among the plurality of element regions in a plan view;
an organic layer disposed inside the opening, disposed on the plurality of inorganic layers, and overlapping the first element region in a plan view;
a transistor disposed between the base layer and the organic layer and disposed in the first element region; and
a light emitting element disposed on the organic layer and electrically connected to the transistor,
wherein an inner surface of the at least some of the inorganic layers defining the opening surrounding the first element region has a substantially polygonal shape in a plan view, the polygonal shape including corners having a shape selected from an outwardly convex curve shape and circular shape in a plan view.

15. A display device comprising:
a base layer including a plurality of element regions and a boundary region adjacent to the plurality of element regions;
a plurality of inorganic layers disposed on the base layer and including an opening defined in at least some of the inorganic layers, the opening corresponding to the boundary region;
an organic layer disposed inside the opening and disposed on the plurality of inorganic layers;
a pixel driving circuit disposed between the base layer and the organic layer, the pixel driving circuit disposed in each of the plurality of element regions; and
a light emitting element disposed on the organic layer and electrically connected to the pixel driving circuit, wherein
the at least some of the inorganic layers define an inorganic stacked structure for each of the plurality of element regions,
the inorganic stacked structure has a circular shape in a plan view,
the plurality of element regions and the boundary region are divided into a plurality of unit regions, each of which has a hexagonal shape in a plan view,
the plurality of element regions and the plurality of unit regions have a one-to-one correspondence, and
a center of the hexagonal shape and a center of the circular shape are coincident.

16. The display device of claim 15, wherein the inorganic stacked structure occupies an area in a range of about 80% to about 90% of an area of each of the plurality of unit regions.

17. The display device of claim 15, wherein
each of the plurality of element regions comprises a first pixel region and a second pixel region,
wherein the pixel driving circuit includes a first pixel driving circuit and a second pixel driving circuit respectively disposed in the first pixel region and the second pixel region, and
wherein the light emitting element includes a first light emitting element and a second light emitting element respectively electrically connected to the first pixel driving circuit and the second pixel driving circuit.

18. The display device of claim 17, wherein
the plurality of element regions comprise a first-type element region and a second-type element region,
the first light emitting element corresponding to the first-type element region and the first light emitting element corresponding to the second-type element region generate light of different colors; and
the second light emitting element corresponding to the first-type element region and the second light emitting element corresponding to the second-type element region generate light of a same color.

19. The display device of claim 15, wherein:
the light emitting element overlaps the opening in a plan view,
the pixel driving circuit comprises a transistor electrically connected to the light emitting element, and
the transistor and the opening do not overlap in a plan view.

20. The display device of claim 15, further comprising:
a thin film encapsulation layer covering the light emitting element;
an input sensor disposed on thin film encapsulation layer; and
a color filter disposed on the input sensor and overlapping the light emitting element.
